(19) United States
(12) Patent Application Publication
(10) Pub. No.: US 2025/0223690 A1
(43) Pub. Date: Jul. 10, 2025

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: Kokusai Electric Corporation, Tokyo (JP)

(72) Inventors: Hajime KARASAWA, Toyama-shi (JP); Yuki YOSHIMOTO, Toyama-shi (JP); Ryota HORIIKE, Toyama-shi (JP); Yoshiro HIROSE, Toyama-shi (JP); Yushin TAKASAWA, Toyama-shi (JP)

(73) Assignee: Kokusai Electric Corporation, Tokyo (JP)

(21) Appl. No.: 19/091,375

(22) Filed: Mar. 26, 2025

Related U.S. Application Data
(63) Continuation of application No. PCT/JP2023/036351, filed on Oct. 5, 2023.

(30) Foreign Application Priority Data
Dec. 22, 2022 (JP) 2022-206063

(51) Int. Cl. C23C 16/42; C23C 16/455; C23C 16/52; H01L 21/02

(52) U.S. Cl. CPC C23C 16/42; C23C 16/45544; C23C 16/52; H01L 21/02532; H01L 21/0262

(57) ABSTRACT

There is provided a technique that includes: (a) supplying a first gas containing a first Group 14 element to a substrate; (b) supplying a second gas containing a second Group 14 element to the substrate; (c) supplying a modifying gas to the substrate; (d) performing (a) n times (where n is an integer of 1 or 2 or more) to form a film containing the first Group 14 element, and then performing at least (b) and (c) m times (where m is an integer of 1 or 2 or more) to form a film containing at least the second Group 14 element; and (e) performing at least (a) and (c) 1 times (where 1 is an integer of 1 or 2 or more) after (d) to form a film containing at least the first Group 14 element.

### CROSS-REFERENCE TO RELATED APPLICATION

This application is a Bypass Continuation Application of PCT International Application No. PCT/JP2023/036351, filed on Oct. 5, 2023 and designating the United States, the international application being based upon and claiming the benefit of priority from Japanese Patent Application No. 2022-206063, filed on Dec. 22, 2022, the entire contents of which are incorporated herein by reference.

### TECHNICAL FIELD

The present disclosure relates to a method of processing a substrate, a method of manufacturing a semiconductor device, a recording medium, and a substrate processing apparatus.

### BACKGROUND

In the related art, in a process of manufacturing a semiconductor device such as a LSI, a film formation process of forming a film containing a Group 14 element on a substrate may be performed.

However, in recent years, there is an increasing demand for miniaturization of semiconductor devices (e.g., 3D NAND type memories). The demand for the miniaturization may include, for example, forming a thin, flat, and uniform film containing a Group 14 element even on a substrate with a fine unevenness on its surface.

### SUMMARY

Some embodiments of the present disclosure provide a technique that contributes to miniaturization of a semiconductor device.

According to some embodiments of the present disclosure, there is provided a technique that includes: (a) supplying a first gas containing a first Group 14 element to a substrate; (b) supplying a second gas containing a second Group 14 element to the substrate; (c) supplying a modifying gas to the substrate; (d) performing (a) n times (where n is an integer of 1 or 2 or more) to form a film containing the first Group 14 element, and then performing at least (b) and (c) m times (where m is an integer of 1 or 2 or more) to form a film containing at least the second Group 14 element; and (e) performing at least (a) and (c) 1 times (where 1 is an integer of 1 or 2 or more) after (d) to form a film containing at least the first Group 14 element.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a substrate processing apparatus used in some embodiments of the present disclosure, in which a portion of a process furnace is shown in a vertical cross-sectional view.

FIG. 2 is a schematic configuration diagram of the substrate processing apparatus used in some embodiments of the present disclosure, in which a portion of the process furnace is shown in a cross-sectional view taken along line A-A in FIG. 1.

FIG. 3 is a schematic configuration diagram of a controller of a substrate processing apparatus used in some embodiments of the present disclosure, in which a control system of the controller is shown in a block diagram.

FIG. 4 is a diagram showing a film formation sequence according to some embodiments of the present disclosure.

FIG. 5 is a diagram showing a film formation sequence according to a first modification.

FIG. 6 is a diagram showing a film formation sequence according to a second modification.

FIG. 7 is a diagram showing a film formation sequence of a third modification.

FIG. 8 is a diagram showing a film formation sequence of a fourth modification.

FIG. 9 is a diagram showing a film formation sequence of a fifth modification.

FIG. 10 is a diagram showing a film formation sequence of a sixth modification.

FIG. 11 is a diagram showing a film formation sequence of a seventh modification.

FIG. 12 is a diagram showing a film formation sequence of an eighth modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Some embodiments of the present disclosure will be described below. Drawings used in the following description are schematic, and dimensional relationships, ratios, and the like of the respective components shown in the drawings may not match actual ones. Furthermore, dimensional relationships, ratios, and the like among plural drawings may not match one another. Furthermore, a numerical range expressed using “to” means a range including numerical values written before and after “to” as a lower limit and an upper limit.

### Embodiments of the Present Disclosure

### Configuration of Substrate Processing Apparatus

The substrate processing apparatus according to the embodiments of the present disclosure is constituted as a batch-and hot-wall-type apparatus (hereinafter, referred to as a substrate processing apparatus) configured to form a film on a wafer.

### Configuration of Process Furnace

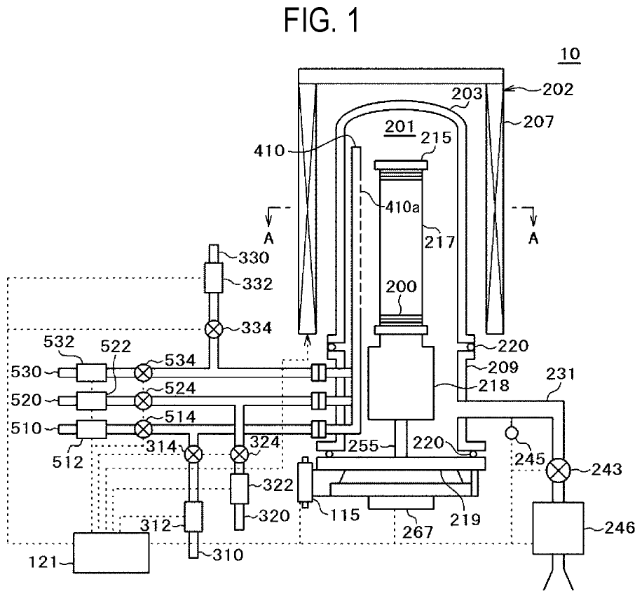

As shown in FIG. 1, a process furnace 202 included in a substrate processing apparatus 10 includes a heater 207 as a heating means or unit (heating mechanism, or heating system). The heater 207 is formed in a cylindrical shape and is supported by a heater base.

A reaction tube 203 constituting a reaction container (a process container) is arranged inside the heater 207 concentrically with the heater 207. The reaction tube 203 is made of a heat-resistant material (e.g., quartz (SiO₂), silicon carbide (SiC), or the like) and is formed in a cylindrical shape with a closed upper end and an open lower end. A manifold 209 (hereinafter referred to as MF 209) is arranged below the reaction tube 203. The MF 209 is made of, for example, a metal such as stainless steel (SUS) and is formed in a cylindrical shape with an open upper end and a closed lower end. An O-ring 220 is installed as a seal between the upper end of the MF 209 and the reaction tube 203. A process chamber 201 in which a substrate is processed is formed in a cylindrical hollow area of the process container.

The process chamber 201 is configured to be capable of accommodating wafers 200 as substrates in such a state that the wafers 200 are arranged in a horizontal posture and in multiple stages along a vertical direction by a boat 217.

Nozzles 410, 420 and 430 are installed in the process chamber 201 so as to penetrate a sidewall of the MF 209. Gas supply pipes 310, 320, and 330 are connected to the nozzles 410, 420, and 430, respectively.

At the gas supply pipes 310, 320, and 330, mass flow controllers (MFCs) 312, 322, and 332 as flow rate controllers (flow rate control parts) and valves 314, 324, and 334 as on-off valves are sequentially installed from the upstream side. Gas supply pipes 510, 520, and 530 configured to supply an inert gas are connected to the gas supply pipes 310, 320, and 330 on the downstream sides of the valves 314, 324, and 334, respectively. At the gas supply pipes 510, 520, and 530, MFCs 512, 522, and 532 as flow rate controllers (flow rate control parts) and valves 514, 524, and 534 as on-off valves are sequentially installed from the upstream side, respectively.

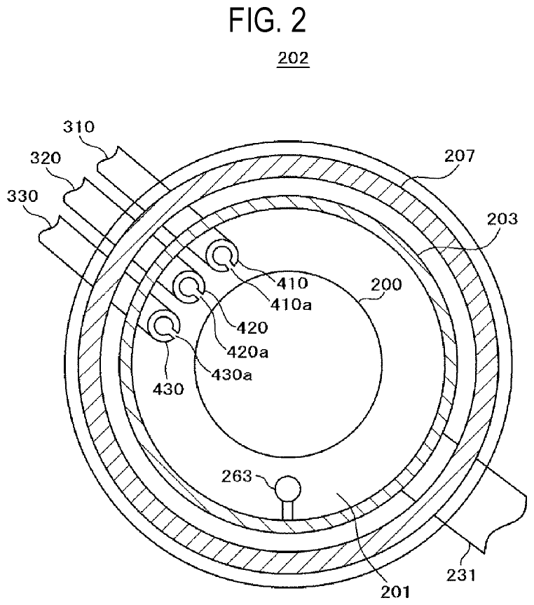

As shown in FIG. 2, the nozzles 410, 420, and 430 are constituted as L-shaped nozzles, and horizontal portions thereof are installed to penetrate the sidewall of the MF 209. Vertical portions of the nozzles 410, 420, and 430 are installed in an annular space formed between an inner wall of the reaction tube 203 and the wafers 200 so as to extend upward (upward in an arrangement direction of the wafers 200) along the inner wall of the reaction tube 203 (i.e., so as to extend upward from one end to the other end of the wafer arrangement region). That is, the nozzles 410, 420, and 430 are installed in a region horizontally surrounding the wafer arrangement region on the lateral side of the wafer arrangement region where the wafers 200 are arranged, so as to extend along the wafer arrangement region.

Gas supply ports 410a, 420a, and 430a configured to supply gases are installed on side surfaces of the nozzles 410, 420, and 430 along the arrangement direction of the wafers 200 so as to correspond to the substrate arrangement region in which the wafers 200 are arranged. The gas supply ports 410a, 420a, and 430a are opened toward a center of the reaction tube 203. The gas supply ports 410a, 420a, and 430a are formed from a lower side to an upper side of the reaction tube 203. The gas supply ports 410a, 420a, and 430a are formed with the same opening area and are arranged at the same opening pitch. However, the gas supply ports 410a, 420a, and 430a are not limited to the above-mentioned form. For example, the opening area may gradually increase from the lower side to the upper side of the reaction tube 203. As a result, flow rates of the gas supplied from the gas supply ports 410a, 420a, and 430a may be uniform.

### Gas Supply System

### First Gas Supply System

A first gas containing a first Group 14 element (hereinafter referred to as first element) is supplied from the gas supply pipe 310 to the process chamber 201 via the MFC 312, the valve 314, and the nozzle 410. An inert gas supply line configured to supply an inert gas such as a nitrogen gas is also connected to the gas supply pipe 310 in parallel, and the inert gas is supplied to the process chamber 201 via the MFC 512, the valve 514, and the nozzle 410. A first gas supply system mainly includes the gas supply pipe 310, the MFC 512, and the valve 514.

### Second Gas Supply System

A second gas containing a second Group 14 element (hereinafter referred to as second element) is supplied from the gas supply pipe 320 to the process chamber 201 via the MFC 322, the valve 324, and the nozzle 420. In addition, a gas supply line configured to supply an inert gas such as a nitrogen gas or a carrier gas such as hydrogen is connected to the gas supply pipe 320 in parallel, and the gas is supplied to the process chamber 201 via the MFC 522, the valve 524, and the nozzle 420. A second gas supply system mainly includes the gas supply pipe 320, the MFC 522, and the valve 524.

### Modifying Gas Supply System

A modifying gas is supplied from the gas supply pipe 330 to the process chamber 201 via the MFC 332, the valve 334, and the nozzle 430. An inert gas supply line configured to supply an inert gas such as a nitrogen gas is connected to the gas supply pipe 320 in parallel, and the inert gas is supplied to the process chamber 201 via the MFC 532, the valve 534, and the nozzle 430. A modifying gas supply system mainly includes the gas supply pipe 330, the MFC 532, and the valve 534.

### Gas Exhaust System

One end of an exhaust pipe 231 as an exhaust flow path configured to exhaust an atmosphere of the process chamber 201 is connected to a wall surface of the MF 209. A pressure sensor 245 as a pressure detector (pressure detection part) configured to detect a pressure in the process chamber 201 and an APC (Auto Pressure Controller) valve 243 as an exhaust valve (pressure regulation part) are attached to the exhaust pipe 231, and a vacuum pump 246 as an exhauster is attached to an end of the exhaust pipe 231. A gas exhaust system mainly includes the exhaust pipe 231, the pressure sensor 245, and the APC valve 243. The vacuum pump 246 may be included in the gas exhaust system.

The APC valve 243 is a valve configured to be capable of performing or stopping the exhaust of the process chamber 201 by being opened or closed while the vacuum pump 246 is operating, and regulating the pressure in the process chamber 201 by adjusting a degree of valve opening based on pressure information detected by the pressure sensor 245 while the vacuum pump 246 is operating. An exhaust system mainly includes the exhaust pipe 231, the APC valve 243, and the pressure sensor 245. The vacuum pump 246 may be included in the exhaust system. The exhaust pipe 231 is not limited to being installed at the MF 209, and may be installed at the reaction tube 203.

A seal cap 219 (hereinafter, referred to as a cap 219) as a furnace opening lid capable of airtightly closing a lower end opening of the MF 209 is installed below the MF 209. The cap 219 is made of a metal such as SUS and formed in a disc shape. An O-ring 220 as a seal that comes into contact with the lower end of the MF 209 is installed on an upper surface of the cap 219. A rotator 267 configured to rotate a boat 217 (described later) is installed on the opposite side of the process chamber 201 from the cap 219. A rotary shaft 255 of the rotator 267 passes through the cap 219 to be connected to the boat 217.

The cap 219 is configured to be raised or lowered in the vertical direction by a boat elevator 115 (hereinafter referred to as elevator 115) as an elevator installed vertically outside the reaction tube 203. The elevator 115 is configured to be capable of loading or unloading the boat 217 into or out of the process chamber 201 by raising or lowering the cap 219. The elevator 115 is constituted as a transfer apparatus configured to transfer the boat 217 into or out of the process chamber 201.

### Boat

The boat 217 serving as a substrate support is configured to support a plurality of wafers 200, for example, 25 to 200 wafers 200, in such a state that the wafers 200 are arranged in a horizontal posture and in multiple stages along a vertical direction. That is, the boat 217 is configured to arrange the wafers to be spaced apart from each other. A top plate 215 is installed at the top of the boat 217. The boat 217 and the top plate 215 are made of a heat-resistant material such as quartz or SiC. In an insulating region at the bottom of the boat 217, insulating plates 218 made of a heat-resistant material are supported in a horizontal posture and in multiple stages.

### Heater

As shown in FIG. 2, a temperature sensor 263 as a temperature detector is installed in the process chamber 201. A temperature distribution in the process chamber 201 becomes a desired temperature distribution by regulating a state of supplying an electrical power to the heater 207 based on the temperature information detected by the temperature sensor 263. The temperature sensor 263 is installed along the inner wall of the reaction tube 203 in the same manner as the nozzles 410, 420, and 430.

### Controller

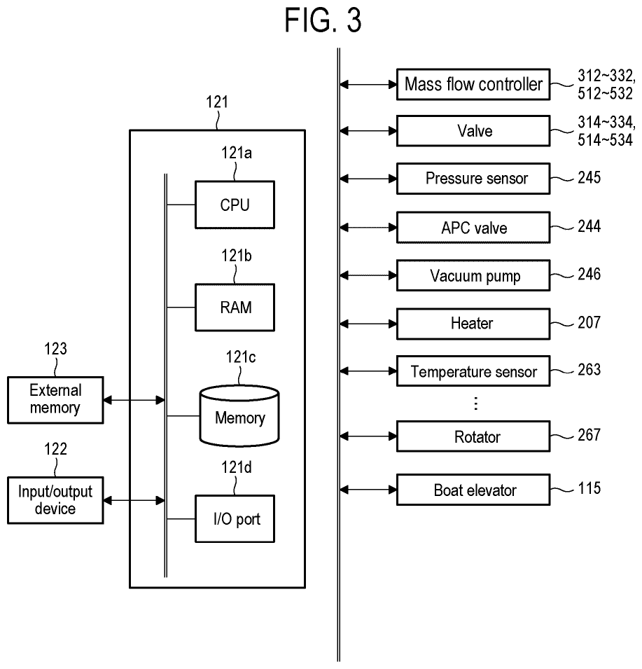

As shown in FIG. 3, a controller 121, which is a control part (control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus. An input/output device 122 constituted as, for example, a touch panel is connected to the controller 121. The substrate processing apparatus may be configured to include one controller or multiple controllers. That is, a control to perform a sequence to be described later may be executed by using one controller or multiple controllers. Further, the multiple controllers may be constituted as a control system in which the controllers are connected to each other by a wired or wireless communication network, and a control to perform a sequence to be described later may be executed by the entire control system. In the present disclosure, when the term “controller” is used, it may include one controller, multiple controllers, or a control system constituted by multiple controllers.

The memory 121c is constituted by, for example, a flash memory, a hard disk drive (HDD), a solid state drive (SSD), etc. At least one selected from the group of a control program to control an operation of the substrate processing apparatus, a process recipe (also referred to as a recipe) in which respective procedures (respective processes, and respective steps) and conditions of a method of processing a semiconductor and a method of manufacturing a semiconductor device are written, and the like are readably stored in the memory 121c. The recipe functions as a program that is combined to allow the controller 121 to execute each procedure to obtain a predetermined result. Hereinafter, the recipe, the control program, and the like are generally and simply referred to as a program. When the term “program” is used in the present disclosure, it may include a recipe, a control program, or a combination thereof. The RAM 121b is constituted as a memory region in which programs and data read by the CPU 121a are temporarily held.

The I/O port 121d is connected to at least one selected from the group of the MFCs 312, 322, 332, 512, 522, and 532, the valves 314, 324, 334, 514, 524, and 534, the pressure sensor 245, the APC valve 243, the vacuum pump 246, the heater 207, the temperature sensor 263, the rotator 267, the elevator 115, and the like.

The CPU 121a is configured to read a control program from the memory 121c and execute the control program thus read, and is also configured to read a recipe or the like from the memory 121c in response to an input of an operation command from the input/output device 122. The CPU 121a is configured to be capable of controlling flow rate regulating operations of the various gases by the MFCs 312, 322, 332, 512, 522, and 532, opening/closing operations of the valves 314, 324, 334, 514, 524, and 534, an opening/closing operation of the APC valve 243, a pressure regulating operation by the APC valve 243 based on the pressure sensor 245, a temperature regulating operation of the heater 207 based on the temperature sensor 263, start and stop of the vacuum pump 246, rotation and rotation speed adjustment operation of the boat 217 by the rotator 267, an operation of raising or lowering the boat 217 by the elevator 115, and the like, according to contents of the read recipe.

The controller 121 may be constituted by installing, on a computer, the above-mentioned program stored in an external memory (e.g., a magnetic disk such as a hard disk, an optical disc such as a CD or a DVD, or a semiconductor memory such as a USB memory or a memory card) 123. The memory 121c and the external memory 123 are constituted as computer-readable recording medium. Hereinafter, these are generally and simply referred to as recording medium. In the present disclosure, the recording medium may include the memory 121c, the external memory 123, or both. The program may be provided to the computer by using a communication means or unit such as the Internet or a dedicated line, instead of using the external memory 123.

### Process of Processing Substrate

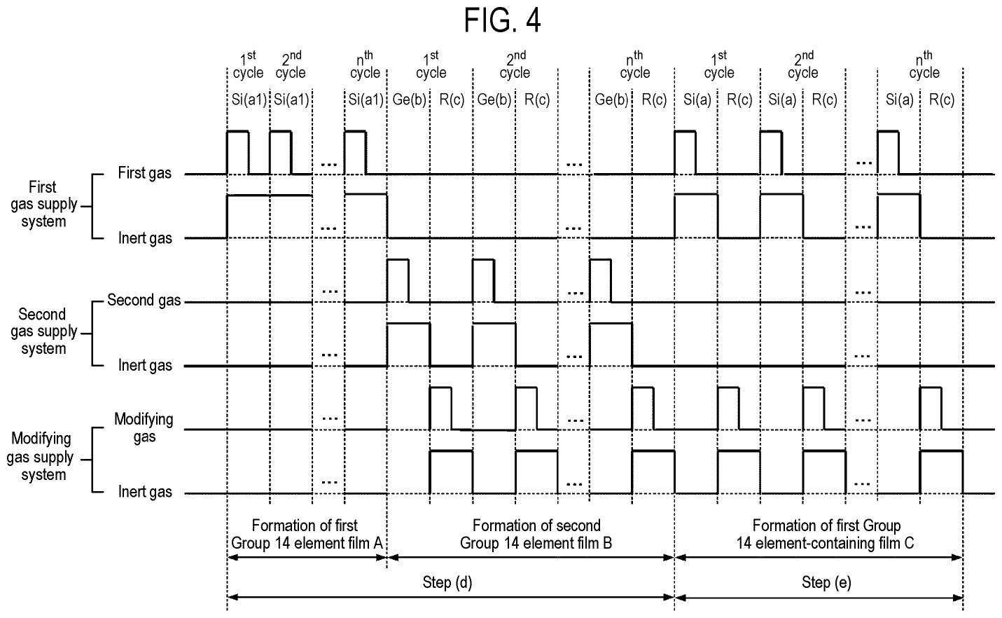

Next, as a process of manufacturing a device according to embodiments of the present disclosure (i.e., a method of processing a substrate), an example of a method of manufacturing a device by forming a film on a wafer 200 as the substrate by using the above-described substrate processing apparatus 10 will be described with reference to FIG. 4. In the following description, an operation of each component constituting the substrate processing apparatus 10 is controlled by the controller 121.

In a film formation sequence shown in FIG. 4, (a) step Si(a) of supplying a first gas containing a first element to a wafer 200, (b) step Ge(b) of supplying a second gas containing a second element to the wafer 200, and (c) step R(c) of supplying a modifying gas to the wafer 200 are performed. In FIG. 4, by using steps Si(a), Ge(b), and R(c), (d) performing step Si(a) n times (where n is an integer of 1 or 2 or more) to form a film containing the first element (hereinafter also referred to as a “first element film A”) and then performing step Ge(b) and step R(c) m times (where m is an integer of 1 or 2 or more) to form a film containing the second element (hereinafter also referred to as a “second element film B”) on the wafer 200, and (e) after step (d), performing step Si(a) and step R(c) 1 times (where l is an integer of 1 or 2 or more) to form a film containing the first element (hereinafter also referred to as “first element film C”) on the wafer 200 are performed. Herein, step Si(a) performed first in step (e) is denoted as “step Si(a1).”

In FIG. 4, in step (d), step R(c) is performed after step Ge(b). Further, in step (e), step R(c) is performed after step Si(a).

In the present disclosure, for the sake of convenience, the above-mentioned processing sequence may be denoted as follows. Similar notation will be used in the description of other embodiments, modifications, and the like.

{[Si(a1)×n]→[(Ge(b)→R(c))×n]}→(e) [(Si(a)→R(c))×n] (d)

The term “wafer” used herein may refer to “a wafer itself” or “a stacked body (aggregate) of a wafer and a predetermined layer or film formed on a surface of the wafer” (that is, the term “wafer” may include the predetermined layer or film formed on the surface of the wafer). Furthermore, the phrase “a surface of a wafer” used herein may refer to “a surface (an exposed surface) of a wafer itself” or “a surface of a predetermined layer or film formed on a wafer, i.e., an outermost surface of a wafer as a stacked body.” In addition, the term “substrate” used herein is synonymous with the term “wafer.”

Each process of the method of processing the substrate according to the embodiments of the present disclosure will be described below.

### Substrate Loading

Multiple wafers 200 are loaded into the process chamber 201. Specifically, when multiple wafers 200 are charged to the boat 217, as shown in FIG. 1, the boat 217 supporting the multiple wafers 200 is lifted up by the elevator 115 and loaded into the process chamber 201. In this state, the cap 219 closes the lower end opening of the MF 209 via the O-ring 220.

### Pressure Regulation and Temperature Regulation

An inside of the process chamber 201 is exhausted by the vacuum pump 246 to reach a desired pressure. At this time, an internal pressure of the process chamber 201 is measured by the pressure sensor 245, and the APC valve 243 is controlled based on the measured pressure information (pressure regulation). Further, the inside of the process chamber 201 is also heated by the heater 207 to reach a desired temperature. At this time, a state of supplying an electrical power supplied to the heater 207 is controlled based on the temperature information detected by the temperature sensor 263 such that a temperature distribution in the process chamber 201 becomes a desired temperature distribution (temperature regulation). The heating of the inside of the process chamber 201 by the heater 207 continues at least until the processing of the wafers 200 is completed.

Further, the boat 217 and the wafers 200 are rotated by the rotator 267. The rotation of the boat 217 and the wafers 200 by the rotator 267 continues at least until the processing of the wafers 200 is completed.

### Film Formation

Next, film formation is performed according to a film formation sequence shown in FIG. 4.

### Step (d)

In step (d), first, step Si(a1) is performed n times (where n is an integer of 1 or 2 or more). In step Si(a1), a first gas containing a first element is supplied to the wafer 200 in the process chamber 201. Specifically, the valve 314 is opened to allow the first gas to flow through the gas supply pipe 310. A flow rate of the first gas is regulated by the MFC 312. The first gas is supplied from the gas supply ports 410a into the process chamber 201 via the nozzle 410, and is exhausted via the exhaust pipe 231. At this time, the first gas is supplied to the wafer 200. At the same time, the valve 514 is opened to allow an inert gas to flow through the gas supply pipe 310. A flow rate of the inert gas is regulated by the MFC 512. The inert gas is supplied into the process chamber 201 together with the first gas, and is exhausted via the exhaust pipe 231. By supplying the first gas containing the first element to the wafer 200, a first element film is formed.

After the formation of the first element film A is completed, the valve 314 is closed to stop the supply of the first gas. At this time, the APC valve 243 is left open to exhaust the inside of the process chamber 201 and remove the first gas remaining in the process chamber 201 from the inside of the process chamber 201. The valve 514 is left open to maintain the supply of the inert gas into the process chamber 201. The inert gas acts as a purge gas.

In step (d), step Si(a1) performs the above-described operation n times (where n is an integer of 1 or 2 or more).

In step (d), a first element film A is formed by step Si(a1). Herein, in step Si(a1), a Si seed layer may be formed as the first element film A.

Processing conditions in step (a1) of step (d) are exemplified as follows:
Supply flow rate of first gas: 10 to 1,000 sccm
Supply time of first gas: 0.1 to 30 minutes
Supply flow rate of inert gas: 10 to 3,000 sccm
Processing temperature: 250 to 650 degrees C.
Processing pressure: 1 to 1,000 Pa.

In the present disclosure, the processing temperature refers to a temperature of the wafer 200 or an internal temperature of the process chamber 201. The processing pressure refers to an internal pressure of the process chamber 201. The supply time of gas refers to a time during which the gas supply continues. The same applies to the following description.

In step (d), the number of cycles of step Si(a1) is, for example, 1 to 300 times, and may be 1 time.

In the present disclosure, the first gas may be a gas containing a Si element as the first element. Examples of the gas containing Si include silicon hydride gases such as a disilane (Si₂H₆) gas, a monosilane (SiH₄) gas, a trisilane (Si₃H₈) gas, a tetrasilane (Si₄H₁₀) gas, a pentasilane (Si₅H₁₂) gas, and a hexasilane (Si₆H₁₄) gas.

In step (d), next, step Ge(b) and step R(c) are performed m times (where m is an integer of 1 or 2 or more).

In step (d), first, step Ge (b) is performed. In step Ge (b), a second gas containing a second Group 14 element (hereinafter referred to as second element) is supplied to the wafer 200 in the process chamber 201. Specifically, the valve 324 is opened to allow the second gas to flow through the gas supply pipe 320. A flow rate of the second gas is regulated by the MFC 322. The second gas is supplied from the gas supply port 420a into the process chamber 201 via the nozzle 420, and is exhausted via the exhaust pipe 231. At this time, the second gas is supplied to the wafer 200. At the same time, the valve 524 is opened to allow an inert gas to flow through the gas supply pipe 320. A flow rate of the inert gas is regulated by the MFC 522. The inert gas is supplied into the process chamber 201 together with the second gas, and is exhausted via the exhaust pipe 231. By supplying the first gas containing the second element to the wafer 200, a second element film before modification is formed.

After the formation of the second element film B is completed, the valve 324 is closed to stop the supply of the second gas. At this time, the APC valve 243 is left open to exhaust the inside of the process chamber 201 and remove the second gas remaining in the process chamber 201 from the inside of the process chamber 201. The valve 524 is left open to maintain the supply of the inert gas into the process chamber 201. The inert gas acts as a purge gas.

In step (d), step R(c) is performed next. In step R(c), a modifying gas is supplied to the wafer 200 in the process chamber 201. Specifically, the valve 334 is opened to allow the modifying gas to flow through the gas supply pipe 330. A flow rate of the modifying gas is regulated by the MFC 332. The modifying gas is supplied from the gas supply port 430a into the process chamber 201 via the nozzle 430, and is exhausted via the exhaust pipe 231. At this time, the modifying gas is supplied to the wafer 200. At the same time, the valve 534 is opened to allow an inert gas to flow through the gas supply pipe 330. A flow rate of the inert gas is regulated by the MFC 532. The inert gas is supplied into the process chamber 201 together with the modifying gas, and is exhausted via the exhaust pipe 231. By supplying the modifying gas to the wafer 200, the second element film is modified.

After the modification of the second element film is completed, the valve 334 is closed to stop the supply of the modifying gas. At this time, the APC valve 243 is left open to exhaust the inside of the process chamber 201 and remove the modifying gas remaining in the process chamber 201 from the inside of the process chamber 201. The valve 534 is left open to maintain the supply of the inert gas into the process chamber 201. The inert gas acts as a purge gas.

In step (d), the above-described operation is performed m times (where m is an integer of 1 or 2 or more) in steps Ge(b) and R(c).

In step (d), a second element film B is formed by step Ge(b) and step R(c). Herein, in step Ge(b) and step R(c), a Ge seed layer may be formed as the second element film.

Processing conditions in step Ge(b) of step (d) are exemplified as follows:
Supply flow rate of second gas: 10 to 1,000 sccm
Supply time of second gas: 0.1 to 30 minutes
Supply flow rate of inert gas: 10 to 3,000 sccm
Processing temperature: 250 to 650 degrees C.
Processing pressure: 1 to 1,000 Pa.

Herein, the second gas may a gas containing a Ge element as the second element. Further, the second gas may be a gas containing at least one organic group in one molecule. The organic group is a group that bonds to the second element. Specifically, the second gas may be a gas containing a structure of a formula: RGeX. In the formula, R is a group (also referred to as a residue, a substituent, or a ligand), and is, for example, an organic group. The gas containing the organic group may be a gas containing at least one selected from the group of a methyl group (CH₃—), an ethylenyl group (C₂H₃—), an ethyl group (C₂H₅—), an isopropyl group (C₃H₇—), and a butyl group (C₄H₉—) as the organic group R. However, the gas containing a butyl group (C₄H₉—) as the organic group also includes an isomer. In the formula, X contains at least one selected from the group of a hydrogen (H) atom, the above-mentioned organic group, and an amino group. Specific examples of the second gas include a tertiary-butyl germane (tert-BuGeH₃) gas, a dimethylamino germane gas, a diethylamino germane gas, a bismethylamino germane gas, a bisdiethylamino germane gas, and a trisdimethylamino germane gas.

Processing conditions in step R (c) of step (d) are exemplified as follows:
Supply flow rate of modifying gas: 10 to 1,000 sccm
Supply time of modifying gas: 0.1 to 30 minutes
Supply flow rate of inert gas: 10 to 3,000 sccm
Processing temperature: 250 to 650 degrees C.
Processing pressure: 1 to 1,000 Pa

Herein, the modifying gas is a gas that causes a density of adsorption sites on an inner surface of a hole of the film to be uniform. The modifying gas may include a gas containing a halogen group, a gas containing an amino group, and a plasma-excited gas. Among these gases, from the viewpoint of homogenization of the film, the gas containing an amino group and the plasma-excited gas may be used. The gas containing a halogen group causes a halogen group to be adsorbed on the film. Examples of the gas containing a halogen group include HCl, Cl₂, and NF₃. The gas containing an amino group causes an amino group to be adsorbed on the film. Examples of the gas containing an amino group include triethylamine. The plasma-excited gas causes H, NH, and O to be adsorbed on the film, or removes undesired groups from the film. Examples of the plasma-excited gas include H₂, D₂, He, N₂, O₂, Ar, NH₃, and ND₃.

In step (d), the number of cycles of steps Ge(b) and R(c) is, for example, 1 to 300. A thickness of the second element film B to be formed is, for example, 1 to 20 nm.

### Step (e)

In step (e), after step (d), step Si(a) and step R(c) are performed 1 times (where 1 is an integer of 1 or 2 or more).

In step (e), first, step Si(a) is performed. In step Si(a), a first gas containing a first element is supplied to the wafer 200 in the process chamber 201. Specifically, the valve 314 is opened to allow the first gas to flow through the gas supply pipe 310. A flow rate of the first gas is regulated by the MFC 312. The first gas is supplied from the gas supply ports 410a into the process chamber 201 via the nozzle 410, and is exhausted via the exhaust pipe 231. At this time, the first gas is supplied to the wafer 200. At the same time, the valve 514 is opened to allow an inert gas to flow through the gas supply pipe 310. A flow rate of the inert gas is regulated by the MFC 512. The inert gas is supplied into the process chamber 201 together with the first gas, and is exhausted via the exhaust pipe 231. By supplying the first gas containing a first element to the wafer 200, an amorphous, epitaxial, or polycrystalline first element film is formed.

After the formation of the first element film C is completed, the valve 314 is closed to stop the supply of the first gas. At this time, the APC valve 243 is left open to exhaust the inside of the process chamber 201, and the first gas remaining in the process chamber 201 is removed from the inside of the process chamber 201. The valve 514 is left open to maintain the supply of the inert gas into the process chamber 201. The inert gas acts as a purge gas.

In step (d), step R(c) is performed next. In step R(c), a modifying gas is supplied to the wafer 200 in the process chamber 201. Specifically, the valve 334 is opened to allow the modifying gas to flow through the gas supply pipe 330. A flow rate of the modifying gas is regulated by the MFC 332. The modifying gas is supplied from the gas supply ports 430a into the process chamber 201 via the nozzle 430, and is exhausted via the exhaust pipe 231. At this time, the modifying gas is supplied to the wafer 200. At the same time, the valve 534 is opened to allow an inert gas to flow through the gas supply pipe 330. A flow rate of the inert gas is regulated by the MFC 532. The inert gas is supplied into the process chamber 201 together with the modifying gas, and is exhausted from the exhaust pipe 231. By supplying the modifying gas to the wafer 200, the first element film is modified.

After the modification of the first element film is completed, the valve 334 is closed to stop the supply of the modifying gas. At this time, the APC valve 243 is left open to exhaust the inside of the process chamber 201 and remove the modifying gas remaining in the process chamber 201 from the inside of the process chamber 201. The valve 534 is left open to maintain the supply of the inert gas into the process chamber 201. The inert gas acts as a purge gas.

In step (e), the above-described operation is performed 1 times (where 1 is an integer of 1 or 2 or more) in step Si(a) and step R(c).

In step (e), a modified first element film C is formed by steps Si(a) and R(c).

Specifically, in steps Si(a) and R(c), a Si layer is formed as the first element film A.

Processing conditions in step Si(a) of step (e) are exemplified as follows:
Supply flow rate of first gas: 10 to 1,000 sccm
Supply time of first gas: 0.1 to 30 minutes
Supply flow rate of inert gas: 10 to 3,000 sccm
Processing temperature: 250 to 650 degrees C.
Processing pressure: 1 to 1,000 Pa

Herein, the first gas may be a gas containing Si as the first element. Examples of the first gas include gases which are the same as those used in step (a1) of step (d).

Processing conditions in step R(c) of step (e) are exemplified as follows:
Supply flow rate of modifying gas: 10 to 3,000 sccm
Supply time of modifying gas: 0.1 to 30 minutes
Supply flow rate of inert gas: 10 to 3,000 sccm
Processing temperature: 250 to 650 degrees C.
Processing pressure: 1 to 1,000 Pa.

The modifying gas may be, for example, gases which are the same as those used in step R(c) of step (d).

In step (d), the number of cycles of steps Si(a) and R(c) is, for example, 1 to 300. A thickness of the first element film C to be formed is, for example, 1 to 20 nm.

### Purging and Returning to Atmospheric Pressure

After film formation is completed, an inert gas such as a N₂ gas is supplied into the process chamber 201 from each of the gas supply pipes 510, 520, and 530, and is exhausted via the exhaust pipe 231. The inert gas acts as a purge gas, and the process chamber 201 is purged with the inert gas. Residual gases and by-products in the process chamber 201 are removed from the process chamber 201. Then, an internal atmosphere of the process chamber 201 is replaced with the inert gas, and an internal pressure of the process chamber 201 is returned to an atmospheric pressure.

### Substrate Unloading

Thereafter, the cap 219 is lowered by the elevator 115, and a bottom end of the MF 209 is opened. Then, the processed wafers 200 supported by the boat 217 are unloaded from the bottom end to the outside of the reaction tube 203. Thereafter, the processed wafers 200 are discharged from the boat 217.

### EFFECTS OF EMBODIMENTS

According to the embodiments of the present disclosure, one or more selected from the group of effects indicated in A) to H) shown below may be obtained. Therefore, the present disclosure may contribute to further miniaturization of semiconductor devices in the future.
A) The film containing the Group 14 element may be formed thinly, flatly, and uniformly.
B) Electrical performance of a channel film of a semiconductor device may be improved.
C) The film containing the Group 14 element may be used as a sacrificial etching film for a silicon film.
D) A first element film A is formed as a seed layer for a second element film B. By providing the first element film A, the second element film B may be formed uniformly on the substrate.
E) In the process of forming the second element film B (i.e., step (d)), by supplying the second gas and the modifying gas, the second element may be uniformly adsorbed on the substrate while removing elements (groups) other than the second element contained in the second gas. In other words, formation of steric hindrance by the molecules of the second gas themselves may be suppressed. As a result, the second element may be uniformly adsorbed on the substrate.

F) In step (d), by using the gas containing an organic group as the second gas, it is possible to promote adsorption of the second element on the substrate, for example, under the conditions when forming the second element film B. As a result, the second element may be formed uniformly on the substrate. A seed layer containing the second element may be formed.
G) In the process of forming the first element-containing film C (i.e., step (e)), by supplying the first gas and the modifying gas, it is possible to uniformly adsorb the first element on the substrate while removing elements (groups) other than the first element contained in the first gas. In other words, it is possible to suppress formation of steric hindrance by the molecules of the first gas themselves. As a result, it is possible to uniformly adsorb the first element on the substrate.
H) By using the gas containing an amine group as the modifying gas, it is possible to cause NH-groups to be adsorbed on the substrate surface while removing elements (groups) other than the Group 14 element from the gas containing the Group 14 element (i.e., the first gas and the second gas). By causing NH-groups to be adsorbed ono the substrate surface, it is possible to improve adsorptivity of the gas containing the Group 14 element (i.e., the first gas and the second gas) to be supplied next. In other words, formation of steric hindrance by the molecules of the gas containing the Group 14 element itself may be suppressed. As a result, the Group 14 element may be uniformly adsorbed on the substrate.
I) By using the plasma-excited gas as the modifying gas, the elements contained in the plasma may be adsorbed on the substrate surface while removing elements (groups) other than the Group 14 element from the gas containing the Group 14 element (i.e., the first gas and the second gas). In other words, the formation of steric hindrance by the molecules of the first gas and the second gas themselves may be suppressed. As a result, the element contained in the plasma may be adsorbed on the substrate surface while the Group 14 element is uniformly adsorbed on the substrate. The element contained in the plasma is, for example, at least one selected from the group of H, NH, and O. By causing the at least one of them to be adsorbed, adsorptivity of the gas containing the Group 14 element to be supplied next (i.e., the first gas and the second gas) may be improved.
J) By using the gas containing a halogen group as the modifying gas, it is possible to cause halogen to be adsorbed on the substrate surface while removing elements (groups) other than the Group 14 element from the gas containing the Group 14 element (i.e., the first gas and the second gas). Halogen is, for example, chlorine (CI). The halogen is likely to react with H and CHₓ— in the gas containing the Group 14 element (i.e., the first gas and the second gas). The halogen reacts with H and CHₓ— in the gas containing the Group 14 element, and groups such as H and CHₓ— may be removed from the gas containing the Group 14 element. When the halogen is Cl, it is desorbed as HCl and CHₓCl. As a result, it is possible to promote adsorption of the gas containing the Group 14 element on the substrate surface. In addition, the halogen on the substrate surface and H and CHₓ— in the gas containing the Group 14 element react with each other to be desorbed, such that at least a portion of the gas containing the Group 14 element may be adsorbed on the substrate surface.

### Modifications

The embodiments are not limited to the embodiments shown in FIG. 4, and may be modified as in the following modifications. These modifications may be combined as desired. Unless otherwise specified, processing procedures and processing conditions for each step of each modification may be the same as the processing procedures and processing conditions for each step of the film formation sequence described above.

For example, in the embodiments, in step (d), in addition to steps Ge(b) and R(c), step Si(a) may be performed. That is, in step (d), a film containing a first element and a second element may be formed. In the embodiments, specifically, a film containing Si as the first element and Ge as the second element (more specifically, a SiGe seed layer) may be formed. In this case, the processing conditions of step Si(a) in step (d) may be the same as the processing conditions of step Si(a) in step (e).

In addition, in the embodiments, in step (e), in addition to steps Si(a) and R(c), step Ge(b) may be performed. That is, in step (e), a film containing a first element and a second element may be formed. In the embodiments, specifically, a film (more specifically, a SiGe layer) containing Si as the first element and Ge as the second element may be formed.

Furthermore, in the embodiments, in steps (d) and (e), except for step Si(a1) which is performed first, steps performed after each of steps Si(a), Ge(b), and R(c) may be performed at the same timing as the previous steps. Two or more steps being performed at the same timing means that processing periods of the respective steps overlap with each other, and the respective steps may start and end at the same timing or the respective steps may start and end at different timings. When two or more steps are performed at the same timing, for the sake of convenience, the respective steps may be denoted by connecting them with “+.” Specifically, for example, when steps Si(a), Ge(b), and R(c) are performed at the same timing, they may be denoted as follows. Similar notations are used in the following descriptions of other embodiments, modifications, and the like.

(Si(a)+Ge(b)+R(c))

In steps (d) and (e), except for step Si(a1) which is performed first, steps which are performed after each of steps Si(a), Ge(b), and R(c) may be performed at the same time as the previous steps, thereby shortening a film formation time.

Specific modifications of the embodiments will be described below.

### First Modification

[Si(a1)×n]→[(Ge(b)+R(c))×n] (d)

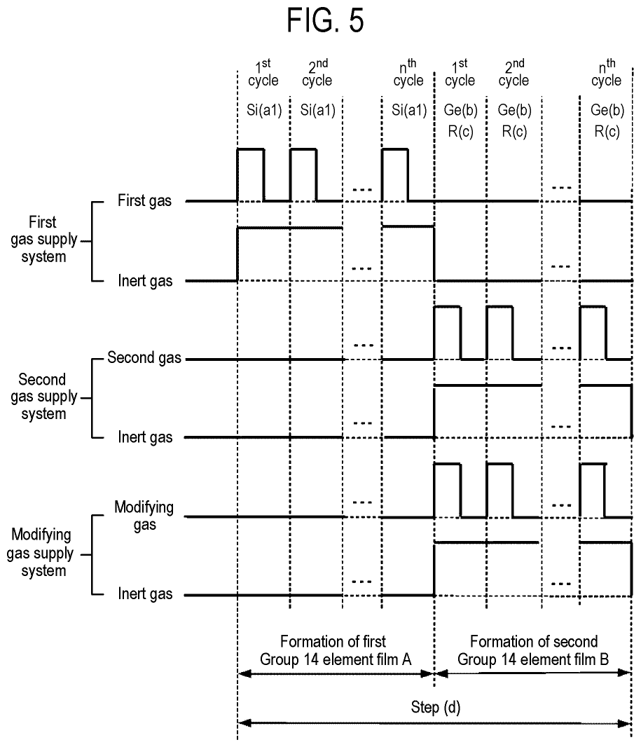

As shown in FIG. 5, in step (d), there may be a timing at which step Ge(b) and step R(c) are performed simultaneously.

### Second Modification

[Si(a1)×n]→[(Ge(b)+Si(a1)→R(c))×n] (d)

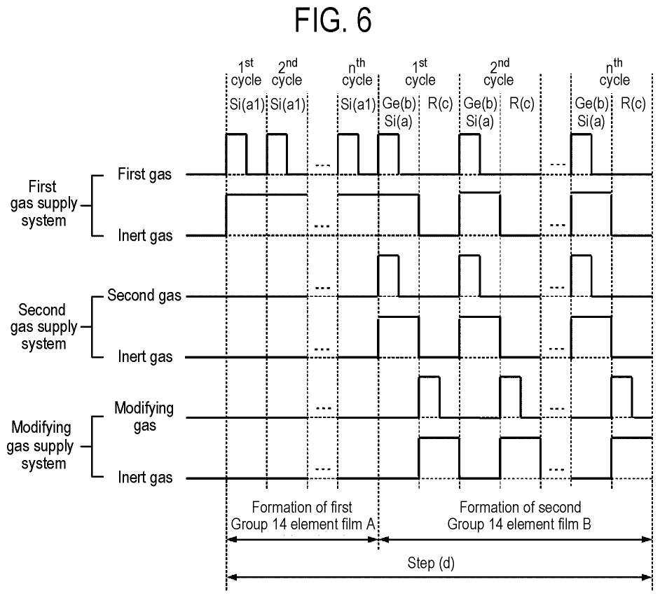

As shown in FIG. 6, in step (d), steps Si(a), Ge(b), and R(c) are performed after step Si(a1), and there may be a timing at which steps Ge(b) and Si(a) are performed simultaneously.

### Third Modification

[Si(a1)×n]→[(Ge(b)+Si(a1)+R(c))×n] (d)

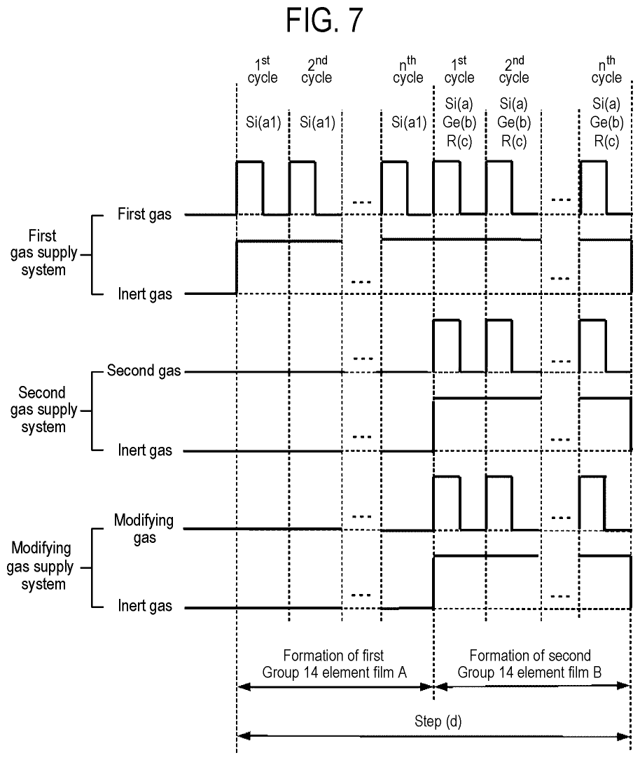

As shown in FIG. 7, in step (d), steps Si(a), Ge(b), and R(c) may be performed after step Si(a1), and there may be a timing at which steps Ge(b), Si(a), and R(c) are performed simultaneously.

### Fourth Modification

[Si(a1)×n]→[(Ge(b)→Si(a1)→R(c))×n] (d)

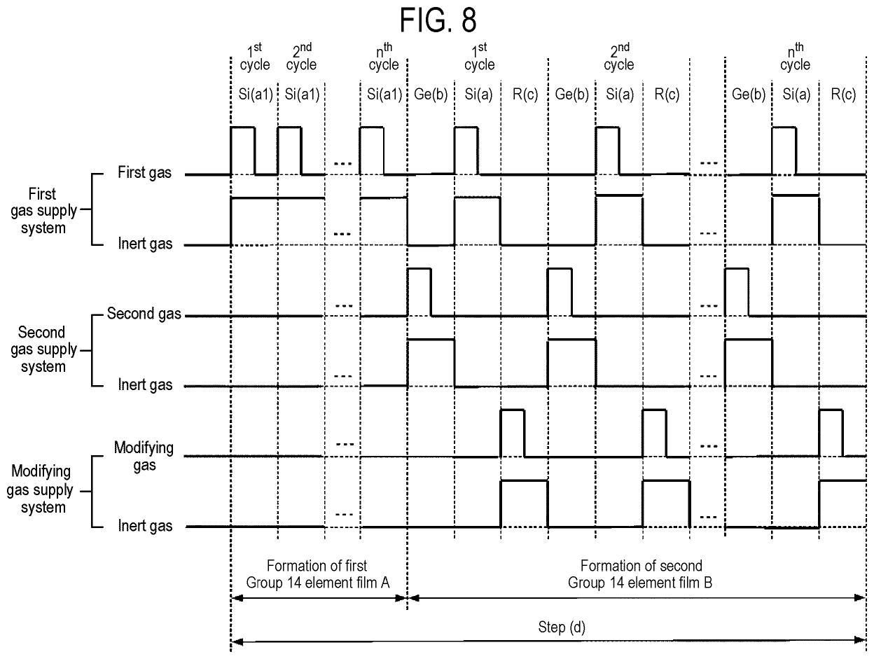

As shown in FIG. 8, in step (d), steps Si(a), Ge(b), and R(c) are performed after step Si(a1), and there may be a timing at which step Si(a) is performed after step Ge(b). In the embodiments, step Si(a) is performed before step R(c).

### Fifth Modification

[Si(a1)×n]→[(Ge(b)→Si(a1)+R(c))×n] (d)

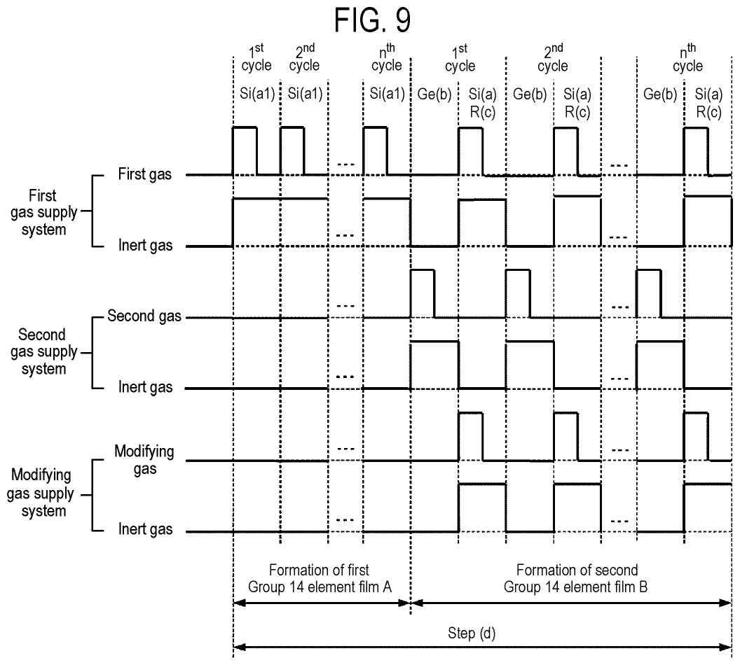

As shown in FIG. 9, in step (d), steps Si(a), Ge(b), and R(c) are performed after step (a1), and there may be a timing at which steps Si (a) and R (c) may be performed simultaneously after step Ge(b).

### Sixth Modification

[(Si(a)+R(c))×n] (e)

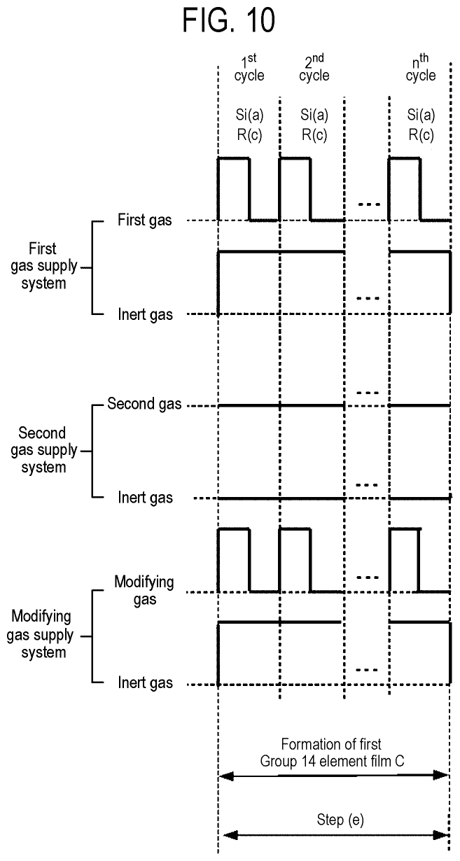

As shown in FIG. 10, in step (e), there may be a timing at which steps Si(a) and R(c) are performed simultaneously.

### Seventh Modification

[(Si(a)+Ge(b)+R(c))×n](e)

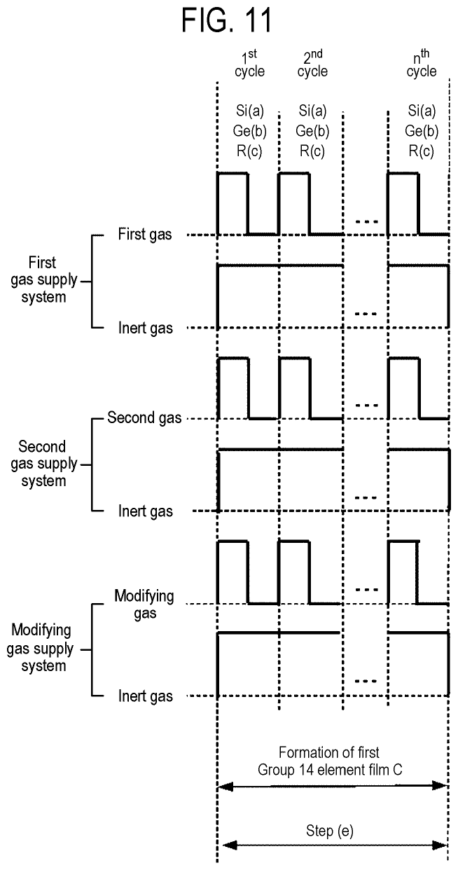

As shown in FIG. 11, in step (e), steps Si(a), Ge(b), and R(c) are performed, and there may be a timing at which and steps Si(a), Ge(b), and R(c) are performed simultaneously.

### Eighth Modification

[(Si(a)+R(c)→Ge(b))×n] (e)

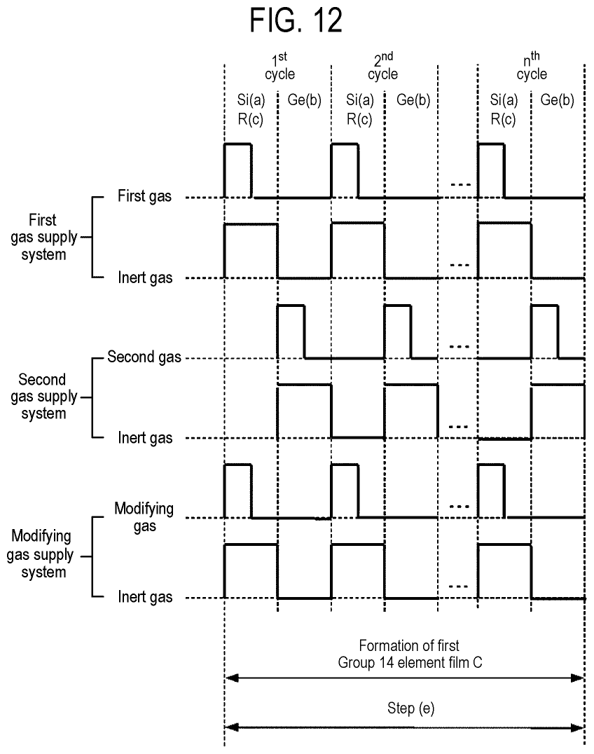

As shown in FIG. 12, in step (e), steps Si(a), Ge(b), and R(c) are performed, and there may be a timing at which steps Si(a) and R(c) are performed simultaneously. Step Ge (b) may be performed after the timing.

In this example, steps Si(a), Ge(b), and R(c) are performed, and there may be a timing at which steps Si(a) and R(c) are performed simultaneously. Step Ge(b) may be performed before the timing.

[(Ge(b)→Si(a)+R(c))×n] (e)

### Other Embodiments

The embodiments of the present disclosure are described above. However, the present disclosure is not limited to the above-described embodiments, and various modifications may be made without departing from the spirit of the present disclosure.

The recipes used when performing the substrate processing may be individually provided according to the processing contents and stored in the memory 121c via an electric communication line or the external memory 123. Then, when starting the substrate processing, the CPU 121a may appropriately select an appropriate recipe from the multiple recipes stored in the memory 121c according to the contents of the substrate processing. This makes it possible to form films of various film types, composition ratios, film qualities, and film thicknesses with good reproducibility by using a single substrate processing apparatus. Further, it is possible to reduce an operator's burden and quickly start processing while avoiding operational errors.

The above-mentioned recipes may be provided newly or may be provided, for example, by modifying the existing recipes that are already installed in the substrate processing apparatus. When modifying the recipe, the modified recipe may be installed in the substrate processing apparatus via an electric communication line or a recording medium on which the recipe are recorded. In addition, the existing recipes that are already installed in the substrate processing apparatus may be directly modified by operating the input/output device 122 included in the existing substrate processing apparatus.

The number of times n, m, and l in each step of the substrate processing described above may be the same or different.

In the above-described embodiments, the examples are described in which the substrate processing apparatus configured to process multiple substrates at a time is used. The present disclosure is not limited to the above-described embodiments, and may be also suitably applied to, for example, a case where a single-substrate type substrate processing apparatus configured to process one or several substrates at a time is used. In addition, in the above-described embodiments, the examples are described in which the substrate processing apparatus including a hot-wall type process furnace is used. The present disclosure is not limited to the above-described embodiments, and may be also suitably applied to, for example, a case where a substrate processing apparatus including a cold-wall type process furnace is used.

In the above-described embodiments, the examples are described in which the above-mentioned processing sequence is performed in the same process chamber of the same processing apparatus (in-situ). The present disclosure is not limited to the above-described embodiments, and for example, any step and another step in the above-mentioned processing sequence may be performed in different process chambers of different processing apparatuses (ex-situ) or performed in different process chambers of the same processing apparatus. When using these substrate processing apparatuses, film formation may be performed in the same sequence and under the same processing conditions as the above-described embodiments and modifications, and the same effects as the above-described embodiments and modifications may be obtained.

Further, the above-described embodiments and modifications may be used in combination as appropriate. Processing procedures and processing conditions in this case may be the same as those of the above-described embodiments.

According to the present disclosure in some embodiments, it is possible to provide a technique that contributes to miniaturization of a semiconductor device.

While certain embodiments are described above, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) supplying a first gas containing a first Group 14 element to a substrate;
(b) supplying a second gas containing a second Group 14 element to the substrate;
(c) supplying a modifying gas to the substrate;
(d) performing (a) n times (where n is an integer of 1 or 2 or more) to form a film containing the first Group 14 element, and then performing at least (b) and (c) m times (where m is an integer of 1 or 2 or more) to form a film containing at least the second Group 14 element; and
(e) performing at least (a) and (c) 1 times (where l is an integer of 1 or 2 or more) after (d) to form a film containing at least the first Group 14 element.

2. The method of claim 1, wherein in (d), (c) is performed after (b).

3. The method of claim 1, wherein (d) includes a timing where (b) and (c) are performed simultaneously.

4. The method of claim 1, wherein in (d), (a), (b), and (c) are performed after (a), and
wherein (d) includes a timing where (b) and (a) are performed simultaneously.

5. The method of claim 2, wherein in (d), (a), (b), and (c) are performed after (a), and
wherein (d) includes a timing where (b) and (a) are performed simultaneously.

6. The method of claim 3, wherein in (d), (a), (b), and (c) are performed after (a), and
wherein (d) includes a timing where (b) and (a) are performed simultaneously.

7. The method of claim 2, wherein in (d), (a), (b), and (c) are performed after (a), and (a) is performed after (b).

8. The method of claim 1, wherein in (d), (a), (b), and (c) are performed after (a), and
wherein (d) includes a timing where (a) and (c) are performed simultaneously after (b).

9. The method of claim 1, wherein (e) includes a timing where (a) and (c) are performed simultaneously.

10. The method of claim 1, wherein in (e), (a), (b), and (c) are performed, and
wherein (e) includes a timing where (a), (b), and (c) are performed simultaneously.

11. The method of claim 1, wherein in (e), (a), (b), and (c) are performed, and
wherein (e) includes a timing where (a) and (c) are performed simultaneously, and (b) is performed after the timing.

12. The method of claim 1, wherein in (e), (c) is performed after (a).

13. The method of claim 1, wherein the first gas contains Si as the first Group 14 element.

14. The method of claim 1, wherein the second gas contains Ge as the second Group 14 element.

15. The method of claim 1, wherein the second gas contains at least one organic group in one molecule.

16. The method of claim 15, wherein the second gas is a gas containing at least one selected from the group of a methyl group, an ethylenyl group, an ethyl group, an isopropyl group, and a butyl group as the organic group.

17. The method of claim 1, wherein the modifying gas includes a gas containing an amine group.

18. A method of manufacturing a semiconductor device, comprising the method of claim 1.

19. A non-transitory computer-readable recording medium storing a program that causes, by a computer, a substrate processing apparatus to perform a process comprising:
(a) supplying a first gas containing a first Group 14 element to a substrate;
(b) supplying a second gas containing a second Group 14 element to the substrate;
(c) supplying a modifying gas to the substrate;
(d) performing (a) n times (where n is an integer of 1 or 2 or more) to form a film containing the first Group 14 element, and then performing at least (b) and (c) m times (where m is an integer of 1 or 2 or more) to form a film containing at least the second Group 14 element; and
(e) performing at least (a) and (c) 1 times (where l is an integer of 1 or 2 or more) after (d) to form a film containing at least the first Group 14 element.

20. A substrate processing apparatus, comprising:
a first gas supply system configured to supply a first gas containing a first Group 14 element to a substrate;
a second gas supply system configured to supply a second gas containing a second Group 14 element to the substrate;
a modifying gas supply system configured to supply a modifying gas to the substrate; and
a controller configured to be capable of controlling the first gas supply system, the second gas supply system, and the modifying gas supply system so as to perform: (a) supplying the first gas containing the first Group 14 element to the substrate; (b) supplying the second gas containing the second Group 14 element to the substrate; (c) supplying the modifying gas to the substrate; (d) performing (a) n times (where n is an integer of 1 or 2 or more) to form a film containing the first Group 14 element, and then performing at least (b) and (c) m times (where m is an integer of 1 or 2 or more) to form a film containing at least the second Group 14 element; and (e) performing at least (a) and (c) 1 times (where 1 is an integer of 1 or 2 or more) after (d) to form a film containing at least the first Group 14 element.
